(19) United States
(12) Patent Application Publication
(10) Pub. No.: US 2026/0190251 A1
(43) Pub. Date: Jul. 2, 2026

(54) DISPLAY APPARATUS AND CENTRAL CONTROL PLATFORM

(71) Applicant: AUO Corporation, Hsinchu City (TW)

(72) Inventors: Chih-Hung Wu, Hsinchu City (TW); Shu-Te Ho, Hsinchu City (TW); Wei-Lun Hung, Hsinchu City (TW)

(73) Assignee: AUO Corporation, Hsinchu City (TW)

(21) Appl. No.: 19/250,077

(22) Filed: Jun. 26, 2025

(30) Foreign Application Priority Data
Dec. 31, 2024 (TW) 113151713

(51) Int. Cl. H05K 5/02

(52) U.S. Cl. CPC H05K 5/0217

(57) ABSTRACT

A display apparatus including a stretchable panel, a telescopic mechanism, a first adhesive layer, and a second adhesive layer is provided. The stretchable panel has an operation surface. The telescopic mechanism is disposed on a side of the stretchable panel opposite to the operation surface and has a receiving surface facing the stretchable panel. The telescopic mechanism is adapted to deform the stretchable panel along a direction intersecting the operation surface. The first adhesive layer connects the stretchable panel and the receiving surface of the telescopic mechanism. The second adhesive layer connects the stretchable panel and the receiving surface of the telescopic mechanism. The second adhesive layer is disposed between an edge of the receiving surface and the first adhesive layer. A Young's modulus of the second adhesive layer is greater than a Young's modulus of the first adhesive layer. A central control platform is also provided.

### CROSS-REFERENCE TO RELATED APPLICATION

This application claims the priority benefit of Taiwan application serial no. 113151713, filed on Dec. 31, 2024. The entirety of the above-mentioned patent application is hereby incorporated by reference herein and made a part of this specification.

### BACKGROUND

### Technical Field

The disclosure relates to a display apparatus and a central control platform, and more particularly to a stretchable display apparatus and a central control platform.

### Description of Related Art

A conventional display apparatus that integrates a stretchable panel and a deformation mechanism features an operation surface capable of deformation. To provide the operation surface with an uneven profile (e.g., a concave or convex surface), the stretchable panel is adhered, via adhesive layers, to multiple independently controlled deformation mechanisms. However, after repeated deformations, the stretchable panel tends to delaminate at the edges of its connection interface with the deformation mechanisms, thereby compromising the deformation performance of the display apparatus.

### SUMMARY

The present disclosure provides a display apparatus and a central control platform in which the connection between the telescopic mechanism and the stretchable panel is more stable.

A display apparatus of the disclosure includes a stretchable panel, a telescopic mechanism, a first adhesive layer, and a second adhesive layer. The stretchable panel has an operation surface. The telescopic mechanism is disposed on a side of the stretchable panel opposite to the operation surface and has a receiving surface facing the stretchable panel. The telescopic mechanism is adapted to deform the stretchable panel along a direction intersecting the operation surface. The first adhesive layer connects the stretchable panel and the receiving surface of the telescopic mechanism. The second adhesive layer connects the stretchable panel and the receiving surface of the telescopic mechanism. The second adhesive layer is disposed between an edge of the receiving surface and the first adhesive layer. A Young's modulus of the second adhesive layer is greater than a Young's modulus of the first adhesive layer.

In one embodiment of the disclosure, a ratio of the Young's modulus of the second adhesive layer to the Young's modulus of the first adhesive layer of the display apparatus is greater than or equal to 20 and less than or equal to 700.

In one embodiment of the disclosure, the receiving surface of the telescopic mechanism of the display apparatus has a first width along any direction parallel to the receiving surface. The first adhesive layer has a second width along the any direction. A ratio of the second width to the first width is less than or equal to 0.3.

In one embodiment of the disclosure, the second adhesive layer of the display apparatus surrounds the first adhesive layer and completely covers a portion of the receiving surface not covered by the first adhesive layer.

In one embodiment of the disclosure, the display apparatus further includes another telescopic mechanism and an auxiliary plate. The another telescopic mechanism is disposed on the side of the stretchable panel opposite to the operation surface and is spaced apart from the telescopic mechanism. The auxiliary plate is attached to a back surface of the stretchable panel opposite to the operation surface and is positioned between the telescopic mechanism and the another telescopic mechanism. A first spacing between the auxiliary plate and the edge of the receiving surface of each of the telescopic mechanism and the another telescopic mechanism in any direction parallel to the receiving surface is greater than or equal to 1 mm and less than or equal to 10 mm.

In one embodiment of the disclosure, a Young's modulus of the auxiliary plate of the display apparatus is greater than 1 GPa.

In one embodiment of the disclosure, the display apparatus further includes a support structure, which is disposed on the side of the stretchable panel opposite to the operation surface and has two openings overlapping the stretchable panel and a support portion defining the two openings. The telescopic mechanism and the another telescopic mechanism are respectively connected to the stretchable panel through the two openings. The auxiliary plate is disposed overlapping the support portion of the support structure.

In one embodiment of the disclosure, the support portion of the display apparatus has a sidewall defining any one of the two openings. The auxiliary plate protrudes from the sidewall of the support portion.

In one embodiment of the disclosure, the auxiliary plate of the display apparatus has a plate edge overlapping the any one of the two openings. A second spacing between the plate edge of the auxiliary plate and the sidewall of the support portion in the any direction is greater than or equal to 0.5 mm and less than or equal to 5 mm.

In one embodiment of the disclosure, a width of the support portion of the display apparatus in the any direction is greater than or equal to 0.5 mm and less than or equal to 10 mm.

A central control platform of the disclosure includes a stretchable panel, a plurality of telescopic mechanisms and an auxiliary plate. The stretchable panel has an operation surface. The plurality of telescopic mechanisms are disposed on a side of the stretchable panel opposite to the operation surface and each have a receiving surface facing the stretchable panel. Each of the plurality of telescopic mechanisms is adapted to deform the stretchable panel along a direction intersecting the operation surface. The auxiliary plate is attached to a back surface of the stretchable panel opposite to the operation surface and located between the plurality of telescopic mechanisms. A first spacing between an edge of the receiving surface of each of the plurality of telescopic mechanisms and the auxiliary plate in any direction parallel to the receiving surface is greater than or equal to 1 mm and less than or equal to 10 mm.

In one embodiment of the disclosure, each of the plurality of telescopic mechanisms of the central control platform is adapted to drive a local portion of the stretchable panel to deform inward toward the back surface or outward toward the operation surface.

In one embodiment of the disclosure, an orthographic projection of the plurality telescopic mechanisms of the central control platform on the operation surface is arranged in a honeycomb pattern.

In one embodiment of the disclosure, the central control platform includes a first adhesive layer and a second adhesive layer. The first adhesive layer connects the stretchable panel and the receiving surface of each of the plurality of telescopic mechanisms. The second adhesive layer connects the stretchable panel and the receiving surface of each of the plurality of telescopic mechanisms. The second adhesive layer surrounds the first adhesive layer and covers a portion of the receiving surface not covered by the first adhesive layer.

In one embodiment of the disclosure, a ratio of a Young's modulus of the second adhesive layer to a Young's modulus of the first adhesive layer is greater than or equal to 20 and less than or equal to 700.

In one embodiment of the disclosure, the receiving surface of each of the plurality telescopic mechanisms of the central control platform has a first width along any direction parallel to the receiving surface. The first adhesive layer has a second width along the any direction. A ratio of the second width to the first width is less than or equal to 0.3.

In one embodiment of the disclosure, a Young's modulus of the auxiliary plate of th central control platform is greater than 1 GPa.

In one embodiment of the disclosure, the central control platform further includes support structure. The support structure is disposed on the side of the stretchable panel opposite to the operation surface and has a plurality of openings overlapping the stretchable panel and a support portion defining the plurality of openings. The plurality of telescopic mechanisms are respectively connected to the stretchable panel through the plurality of openings. The auxiliary plate overlaps the support portion of the support structure.

In one embodiment of the disclosure, the support portion of the central control platform has a sidewall defining any one of the plurality of openings. The auxiliary plate protrudes from the sidewall of the support portion.

In one embodiment of the disclosure, the auxiliary plate of the central control platform has a plate edge overlapping the any one of the plurality of openings. A second spacing between the plate edge of the auxiliary plate and the sidewall of the support portion in the any direction is greater than or equal to 0.5 mm and less than or equal to 5 mm.

Based on the above, in a display apparatus according to one embodiment of the disclosure, a receiving surface of a telescopic mechanism is provided with a first adhesive layer and a second adhesive layer, and connects the stretchable panel via these two adhesive layers. Since the second adhesive layer is disposed between an edge of the receiving surface and the first adhesive layer, and a Young's modulus of the second adhesive layer is greater than a Young's modulus of the first adhesive layer, detachment of the stretchable panel from the telescopic mechanism after repeated deformation can be effectively suppressed, which helps to enhance the stability during deformation operations of the display apparatus.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic view of a display apparatus according to a first embodiment of the disclosure.

FIG. 2 is a bottom view of the display apparatus of FIG. 1.

FIG. 3 is a cross-sectional view of the display apparatus of FIG. 1.

FIG. 4A is a cross-sectional view of the display apparatus of FIG. 1 in a locally recessed state.

FIG. 4B is a cross-sectional view of the display apparatus of FIG. 1 in a locally protruded state.

FIG. 5 is a cross-sectional view of a display apparatus according to a second embodiment of the disclosure.

FIG. 6 is a cross-sectional view of a display apparatus according to a third embodiment of the disclosure.

### DESCRIPTION OF THE EMBODIMENTS

The following provides a detailed reference to exemplary embodiments of the disclosure, with illustrative examples described in the accompanying drawings. Wherever possible, the same reference numerals are used in the drawings and the description to refer to the same or similar parts.

It should be understood that when an element such as a layer, film, region, or substrate is described as being “on” or “connected to” another element, it may be directly on or connected to the other element, or there may be intervening elements. Conversely, when an element is described as being “directly on” or “directly connected to” another element, no intervening elements are present. As used herein, “connected” may refer to physical and/or electrical connections. Furthermore, “electrically connected” or “coupled” may include the presence of other elements between the two elements.

As used herein, the terms “about,” “approximately,” or “substantially” include the specified value and an average value within an acceptable range of deviation from the specific value as determined by one of ordinary skill in the art, taking into account the specific magnitude of the discussed measurement and the associated measurement error (i.e., the limitations of the measurement system). For example, “about” may refer to within one or more standard deviations of the stated value, or within ±30%, ±20%, ±10%, or ±5%. Furthermore, the terms “about,” “approximately,” or “substantially,” as used herein, may be chosen based on optical, etching, or other characteristics, such that a single standard deviation does not apply uniformly to all properties.

Unless otherwise defined, all terms used herein (including technical and scientific terms) have the same meaning as commonly understood by one of ordinary skill in the art to which this invention belongs. It will also be understood that terms defined in commonly used dictionaries should be interpreted as having meanings consistent with their meaning in the context of the relevant technical field and this disclosure, and should not be interpreted in an idealized or overly formal sense unless expressly defined herein.

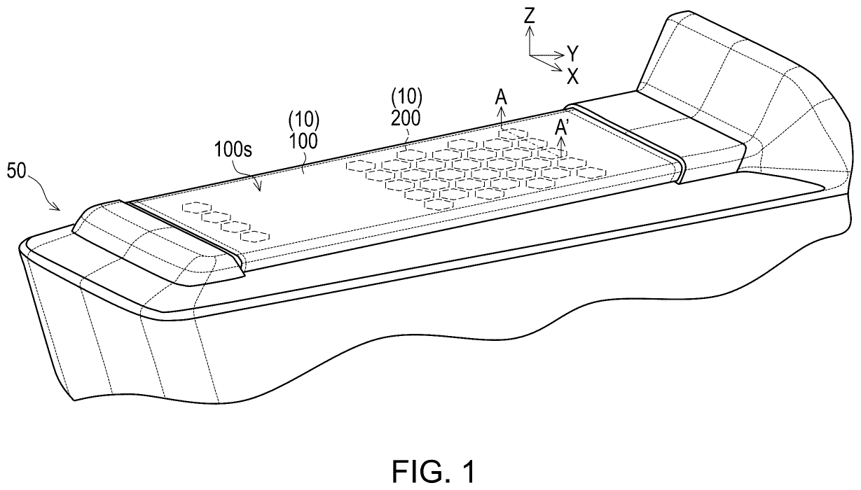

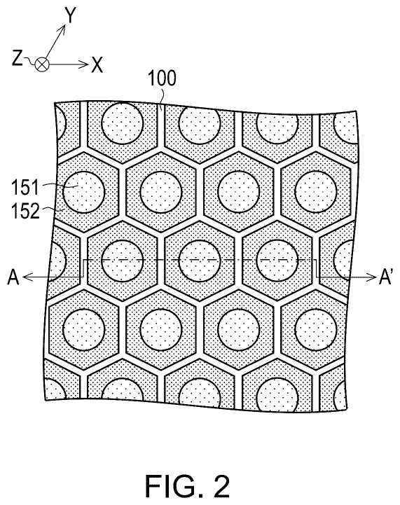

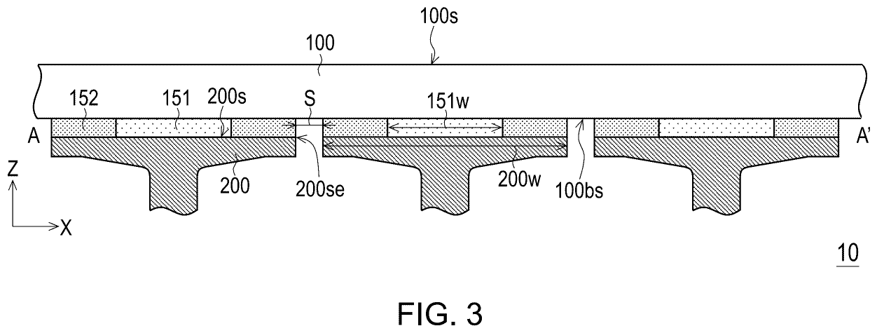

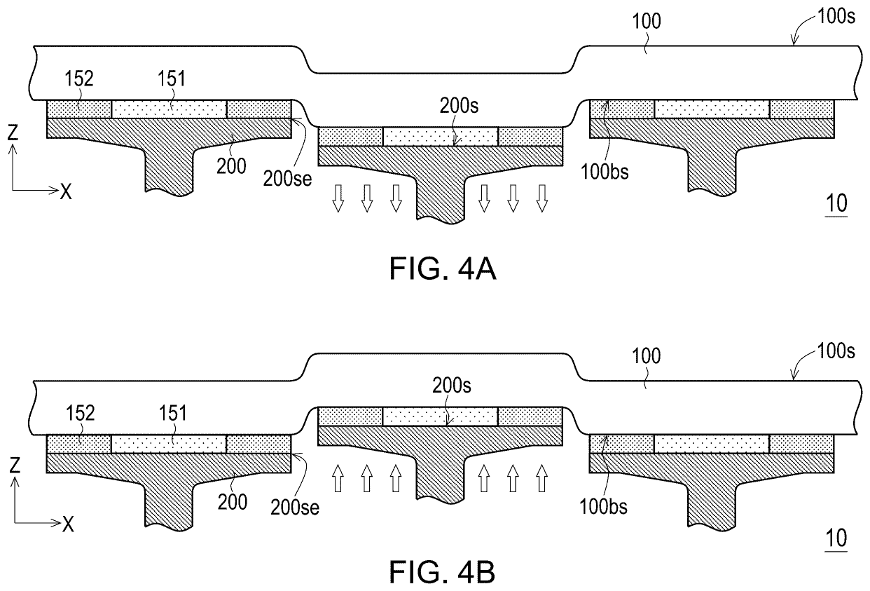

FIG. 1 is a schematic view of a display apparatus according to a first embodiment of the disclosure. FIG. 2 is a bottom view of the display apparatus of FIG. 1. FIG. 3 is a cross-sectional view of the display apparatus of FIG. 1. FIG. 4A is a cross-sectional view of the display apparatus of FIG. 1 in a locally recessed state. FIG. 4B is a cross-sectional view of the display apparatus of FIG. 1 in a locally protruded state. FIG. 3 corresponds to a section line A-A′ of FIG. 1 and FIG. 2. For clarity, FIG. 2 only illustrates a stretchable panel 100, a first adhesive layer 151, and a second adhesive layer 152 in FIG. 3.

Referring to FIG. 1, FIG. 2, and FIG. 3, first, a display apparatus 10 of the embodiment can be applied to in-vehicle display fields, such as a display/operation interface of a central control platform 50, but the disclosure is not limited thereto. In other embodiments, the display apparatus 10 may also be applied to other devices requiring human-machine interfaces.

In detail, the display apparatus 10 includes a stretchable panel 100 and a plurality of telescopic mechanisms 200. The stretchable panel 100 has an operation surface 100s, and these telescopic mechanisms 200 are disposed on a side of the stretchable panel 100 opposite to the operation surface 100s. For example, in the embodiment, the stretchable panel 100 may include a plurality of island-like structures (not shown) with display or touch functions, and bridging structures (not shown) connected between these island-like structures. A spacing between these island-like structures changes as the stretchable panel 100 operates in different deformation states. The stretchable panel 100 may be a display panel, a touch panel, or a combination thereof.

For example, in the embodiment, the plurality of telescopic mechanisms 200 may be arranged at intervals along a direction X and a direction Y, wherein the direction X and the direction Y intersect each other and are perpendicular to direction Z. More specifically, an orthographic projection of the plurality of telescopic mechanisms 200 on the operation surface 100s of the stretchable panel 100 are arranged in a honeycomb pattern in a normal direction (e.g., a direction Z) of the operation surface. However, the disclosure is not limited thereto. In other embodiments, the arrangement of the plurality of telescopic mechanisms 200 may be adjusted according to the actual application of the display apparatus.

In the embodiment, the telescopic mechanism 200 is adapted to drive the stretchable panel 100 to deform along a direction (e.g., direction Z) intersecting the operation surface 100s. More specifically, the telescopic mechanism 200 is used to drive a local portion of the stretchable panel 100 to recess toward a side opposite to the operation surface 100s (as shown in FIG. 4A), or to protrude toward a side of the operation surface 100s (as shown in FIG. 4B). The aforementioned local portion of the stretchable panel 100 is, for example, a portion of the stretchable panel 100 connected to each of the telescopic mechanisms 200.

To establish a connection between the telescopic mechanisms 200 and the stretchable panel 100, the display apparatus 10 further includes a first adhesive layer 151 and a second adhesive layer 152. In detail, the stretchable panel 100 further has a back surface 100bs opposite to the operation surface 100s, and the telescopic mechanism 200 has a receiving surface 200s facing the stretchable panel 100. It should be noted that both the first adhesive layer 151 and the second adhesive layer 152 connect the back surface 100bs of the stretchable panel 100 to the receiving surface 200s of the telescopic mechanism 200.

More specifically, the second adhesive layer 152 is disposed between an edge 200se of the receiving surface 200s and the first adhesive layer 151. For example, in the embodiment, the second adhesive layer 152 surrounds the first adhesive layer 151 and completely covers a portion of the receiving surface 200s not covered by the first adhesive layer 151. That is, the first adhesive layer 151 and the second adhesive layer 152 are arranged side by side on the receiving surface 200s of the telescopic mechanism 200, and in any direction parallel to the receiving surface 200s, the second adhesive layer 152 separates the edge 200se of the receiving surface 200s from the first adhesive layer 151.

From another perspective, the receiving surface 200s of the telescopic mechanism 200 has a width 200w in any direction (e.g., direction X) parallel to the receiving surface 200s, and the first adhesive layer 151 has a width 151w in the any direction. Preferably, a ratio of the width 151w of the first adhesive layer 151 to the width 200w of the receiving surface 200s is less than or equal to 0.3.

It is particularly noted that since a Young's modulus of the second adhesive layer 152 is greater than a Young's modulus of the first adhesive layer 151, when the stretchable panel 100 deforms, the strain generated in the second adhesive layer 152 is lower than that in the first adhesive layer 151. Therefore, the stretchable panel 100 is less likely to peel off from the edge 200se of the receiving surface 200s of the telescopic mechanism 200. In other words, the configuration relationship and material properties of the first adhesive layer 151 and the second adhesive layer 152 can effectively enhance the stability and durability of the display apparatus 10 during deformation operation.

Preferably, a ratio of the Young's modulus of the second adhesive layer 152 to the Young's modulus of the first adhesive layer 151 is greater than or equal to 20 and less than or equal to 700. The Young's modulus of the first adhesive layer 151 may be greater than or equal to 0.01 MPa and less than or equal to 0.1 MPa. The Young's modulus of the second adhesive layer 152 may be greater than or equal to 2 MPa and less than or equal to 7 MPa. The first adhesive layer 151 may be a pressure-sensitive adhesive (PSA) layer, and its material may include rubber, acrylic, silicone, or polyurethane (PU) glue. The second adhesive layer 152 may be a liquid adhesive, and its material may include hydrogel, rubber, acrylic, silicone, resin, epoxy, hot melt adhesive, or silane.

It is particularly worth noting that, in the bonding process between the stretchable panel and the telescopic mechanism 200, pressing the pressure-sensitive adhesive (i.e., the first adhesive layer 151) may prevent misalignment or slippage between the stretchable panel 100 and the telescopic mechanism 200, thereby avoiding misalignment during subsequent processes such as dispensing, pressing, and heat-curing of liquid adhesive (i.e., the second adhesive layer 152). That is, the configuration of the first adhesive layer 151 and the second adhesive layer 152 can also improve the bonding process accuracy and yield between the stretchable panel 100 and the telescopic mechanism 200.

Other embodiments will be listed below to explain the present disclosure in detail, wherein the same components will be marked with the same symbols, and the description of the same technical content will be omitted. For the omitted parts, please refer to the aforementioned embodiment and will not be repeated below.

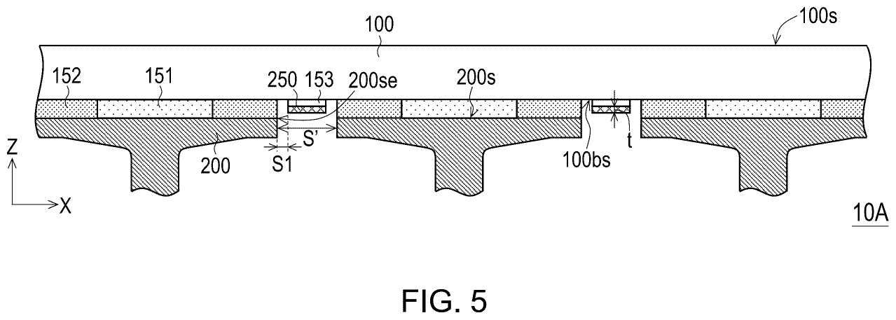

FIG. 5 is a cross-sectional view of a display apparatus according to a second embodiment of the disclosure. Referring to FIG. 5, compared to the display apparatus 10 in FIG. 3, a display apparatus 10A of the embodiment may further include an auxiliary plate 250 attached to the back surface 100bs of the stretchable panel 100. It should be noted that the auxiliary plate 250 is located in a spacing region between the plurality of telescopic mechanisms 200.

Preferably, a Young's modulus of the auxiliary plate 250 may be greater than 1 GPa, and its thickness t may be greater than or equal to 10 μm and less than or equal to 200 μm. The auxiliary plate 250 may be made of materials such as polycarbonate (PC), polymethyl methacrylate (PMMA), polyethylene terephthalate (PET), or stainless steel (SUS).

In the embodiment, in order to increase the protrusion height of the stretchable panel 100 during the deformation shown in FIG. 4B, a spacing S′ between two adjacent telescopic mechanisms 200 along an arrangement direction (e.g., direction X) may be greater than a spacing S between two adjacent telescopic mechanisms 200 in FIG. 3. However, if the spacing between two adjacent telescopic mechanisms 200 is too large, it becomes difficult to maintain the surface flatness of the stretchable panel 100 in its undeformed state; for example, the stretchable panel 100 may easily sink in the spacing region between the two adjacent telescopic mechanisms 200. Therefore, the auxiliary plate 250 can be added to enhance the stiffness of the portion of the stretchable panel 100 located between the plurality of telescopic mechanisms 200.

Preferably, in any direction (e.g., direction X) parallel to the receiving surface 200s, a spacing S1 between the auxiliary plate 250 and the edge 200se of the receiving surface 200s may be greater than or equal to 1 mm and less than or equal to 10 mm. For example, the auxiliary plate 250 may be attached to the back surface 100bs of the stretchable panel 100 via a third adhesive layer 153, which may be a liquid adhesive, but the disclosure is not limited thereto.

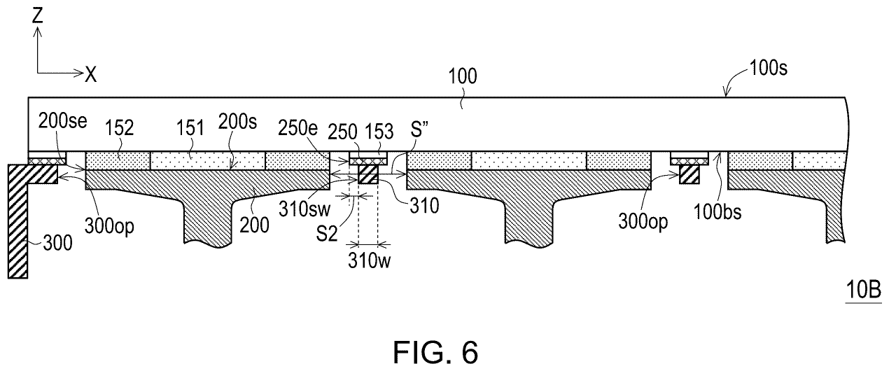

FIG. 6 is a cross-sectional view of a display apparatus according to a third embodiment of the disclosure. Referring to FIG. 6, compared to the display apparatus 10A of FIG. 5, a display apparatus 10B of the embodiment may further include a support structure 300, which is disposed on the side of the stretchable panel 100 opposite to the operation surface 100s.

In detail, the support structure 300 may have a plurality of openings 300op and a support portion 310 defining the plurality of openings 300op. In an actuation direction (e.g., direction Z) of the telescopic mechanisms 200, the plurality of openings 300op of the support structure 300 respectively overlap the plurality of telescopic mechanisms 200, and these telescopic mechanisms 200 are respectively connected to the stretchable panel 100 through these openings 300op.

For example, in the embodiment, a spacing S″ between any two adjacent telescopic mechanisms 200 along an arrangement direction (e.g., direction X) may be greater than the spacing S′ between any two adjacent telescopic mechanisms 200 in FIG. 5. Therefore, when the provision of the auxiliary plate 250 fails to meet the required flatness of the stretchable display panel 100 in the spacing region between two telescopic mechanisms 200, the stiffness of the portion of the stretchable panel 100 located between the plurality of telescopic mechanisms 200 can be further enhanced by additionally providing the support portion 310 of the support structure 300.

In a normal direction (e.g., direction Z) of the receiving surface 200s, the auxiliary plate 250 is disposed overlapping the support portion 310 of the support structure 300. It is particularly noted that the support portion 310 has a sidewall 310sw defining each opening 300op, and the auxiliary plate 250 protrudes from the sidewall 310sw of the support portion 310. From another perspective, the auxiliary plate 250 has a plate edge 250e overlapping the opening 300op in the direction Z. Preferably, in any direction (e.g., direction X) parallel to the receiving surface 200s, a width 310w of the support portion 310 may be greater than or equal to 0.5 mm and less than or equal to 10 mm, and a spacing S2 between the plate edge 250e of the auxiliary plate 250 and the sidewall 310sw of the support portion 310 may be greater than or equal to 0.5 mm and less than or equal to 5 mm.

In summary, in a display apparatus according to one embodiment of the disclosure, a receiving surface of a telescopic mechanism is provided with a first adhesive layer and a second adhesive layer, and connects the stretchable panel via these two adhesive layers. Since the second adhesive layer is disposed between an edge of the receiving surface and the first adhesive layer, and a Young's modulus of the second adhesive layer is greater than a Young's modulus of the first adhesive layer, detachment of the stretchable panel from the telescopic mechanism after repeated deformation can be effectively suppressed, which helps to enhance the stability during deformation operations of the display apparatus.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A display apparatus, comprising:
a stretchable panel, having an operation surface;
a telescopic mechanism, disposed on a side of the stretchable panel opposite to the operation surface and having a receiving surface facing the stretchable panel, the telescopic mechanism is adapted to deform the stretchable panel along a direction intersecting the operation surface;
a first adhesive layer, connecting the stretchable panel and the receiving surface of the telescopic mechanism; and
a second adhesive layer, connecting the stretchable panel and the receiving surface of the telescopic mechanism, wherein the second adhesive layer is disposed between an edge of the receiving surface and the first adhesive layer, and a Young's modulus of the second adhesive layer is greater than a Young's modulus of the first adhesive layer.

2. The display apparatus according to claim 1, wherein a ratio of the Young's modulus of the second adhesive layer to the Young's modulus of the first adhesive layer is greater than or equal to 20 and less than or equal to 700.

3. The display apparatus according to claim 1, wherein the receiving surface of the telescopic mechanism has a first width along any direction parallel to the receiving surface, the first adhesive layer has a second width along the any direction, and a ratio of the second width to the first width is less than or equal to 0.3.

4. The display apparatus according to claim 1, wherein the second adhesive layer surrounds the first adhesive layer and completely covers a portion of the receiving surface not covered by the first adhesive layer.

5. The display apparatus according to claim 1, further comprising:
another telescopic mechanism, disposed on the side of the stretchable panel opposite to the operation surface and spaced apart from the telescopic mechanism; and
an auxiliary plate, attached to a back surface of the stretchable panel opposite to the operation surface and positioned between the telescopic mechanism and the another telescopic mechanism, wherein a first spacing between the auxiliary plate and the edge of the receiving surface of each of the telescopic mechanism and the another telescopic mechanism in any direction parallel to the receiving surface is greater than or equal to 1 mm and less than or equal to 10 mm.

6. The display apparatus according to claim 5, wherein a Young's modulus of the auxiliary plate is greater than 1 GPa.

7. The display apparatus according to claim 5, further comprising:
a support structure, disposed on the side of the stretchable panel opposite to the operation surface and having two openings overlapping the stretchable panel and a support portion defining the two openings, wherein the telescopic mechanism and the another telescopic mechanism are respectively connected to the stretchable panel through the two openings, and the auxiliary plate overlaps the support portion of the support structure.

8. The display apparatus according to claim 7, wherein the support portion has a sidewall defining any one of the two openings, and the auxiliary plate protrudes from the sidewall of the support portion.

9. The display apparatus according to claim 8, wherein the auxiliary plate has a plate edge overlapping the any one of the openings, and a second spacing between the plate edge of the auxiliary plate and the sidewall of the support portion in the any direction is greater than or equal to 0.5 mm and less than or equal to 5 mm.

10. The display apparatus according to claim 7, wherein a width of the support portion in the any direction is greater than or equal to 0.5 mm and less than or equal to 10 mm.

11. A central control platform, comprising:
a stretchable panel, having an operation surface;
a plurality of telescopic mechanisms, disposed on a side of the stretchable panel opposite to the operation surface and each having a receiving surface facing the stretchable panel, wherein each of the plurality of telescopic mechanisms is adapted to deform the stretchable panel along a direction intersecting the operation surface; and
an auxiliary plate, attached to a back surface of the stretchable panel opposite to the operation surface and located between the plurality of telescopic mechanisms, wherein a first spacing between an edge of the receiving surface of each of the plurality of telescopic mechanisms and the auxiliary plate in any direction parallel to the receiving surface is greater than or equal to 1 mm and less than or equal to 10 mm.

12. The central control platform according to claim 11, wherein each of the plurality of telescopic mechanisms is adapted to drive a local portion of the stretchable panel to deform inward toward the back surface or outward toward the operation surface.

13. The central control platform according to claim 11, wherein an orthographic projection of the plurality of telescopic mechanisms on the operation surface is arranged in a honeycomb pattern.

14. The central control platform according to claim 11, further comprising:
a first adhesive layer, connecting the stretchable panel and the receiving surface of each of the plurality of telescopic mechanisms; and
a second adhesive layer, connecting the stretchable panel and the receiving surface of each of the plurality of telescopic mechanisms, wherein the second adhesive layer surrounds the first adhesive layer and covers a portion of the receiving surface not covered by the first adhesive layer.

15. The central control platform according to claim 14, wherein a ratio of a Young's modulus of the second adhesive layer to a Young's modulus of the first adhesive layer is greater than or equal to 20 and less than or equal to 700.

16. The central control platform according to claim 14, wherein the receiving surface of each of the plurality of telescopic mechanisms has a first width along any direction parallel to the receiving surface, the first adhesive layer has a second width along the any direction, and a ratio of the second width to the first width is less than or equal to 0.3.

17. The central control platform according to claim 11, wherein a Young's modulus of the auxiliary plate is greater than 1 GPa.

18. The central control platform according to claim 11, further comprising:
a support structure, disposed on the side of the stretchable panel opposite to the operation surface and having a plurality of openings overlapping the stretchable panel and a support portion defining the plurality of openings, wherein the plurality of telescopic mechanisms are respectively connected to the stretchable panel through the plurality of openings, and the auxiliary plate overlaps the support portion of the support structure.

19. The central control platform according to claim 18, wherein the support portion has a sidewall defining any one of the plurality of openings, and the auxiliary plate protrudes from the sidewall of the support portion.

20. The central control platform according to claim 19, wherein the auxiliary plate has a plate edge overlapping the any one of the plurality of openings, and a second spacing between the plate edge of the auxiliary plate and the sidewall of the support portion in the any direction is greater than or equal to 0.5 mm and less than or equal to 5 mm.
